(19) United States
(12) Patent Application Publication
(10) Pub. No.: US 2026/0150185 A1
(43) Pub. Date: May 28, 2026

(54) FLEXIBLE SUBSTRATE

(71) Applicant: ELECTRONICS AND TELECOMMUNICATIONS RESEARCH INSTITUTE, Daejeon (KR)

(72) Inventors: HANBIT JIN, Daejeon (KR); Hye Jin KIM, Daejeon (KR); Jungrak CHOI, Daejeon (KR)

(21) Appl. No.: 19/328,789

(22) Filed: Sep. 15, 2025

(30) Foreign Application Priority Data
Oct. 10, 2024 (KR) 10-2024-0137615
Dec. 18, 2024 (KR) 10-2024-0190170

(51) Int. Cl. H05K 1/02; H05K 1/09; H05K 1/11

(52) U.S. Cl. CPC H05K 1/028; H05K 1/0283; H05K 1/09; H05K 1/111; H05K 2201/05; H05K 2201/09263; H05K 2201/09272; H05K 2201/09381; H05K 2201/09727

(57) ABSTRACT

A flexible substrate includes a base layer and a pattern portion on the base layer, wherein the pattern portion includes a plurality of line portions extending in a first direction and spaced apart from each other in a second direction perpendicular to the first direction and a plurality of arc portions connecting the line portions to each other, and wherein the widths of the line portions in the second direction increase as they get closer to an edge region of the base layer.

### CROSS-REFERENCE TO RELATED APPLICATIONS

This U.S. non-provisional patent application claims priority under 35 U.S.C. §119 to Korean Patent Application No. 10-2024-0137615, filed on Oct. 10, 2024 and No. 10-2024-0190170, filed on Dec. 18, 2024 in the Korean Intellectual Property Office, the entire contents of which are hereby incorporated by reference.

### BACKGROUND

The present disclosure relates to a flexible substrate, and more particularly, to a flexible substrate in which wiring patterns are formed on an FCCL (Flexible Copper Clad Laminate) film through laser processing or the like.

FCCL (Flexible Copper Clad Laminate) film is a type of film in which copper is laminated on a polyimide, and is used in electronic devices and circuit boards that require flexibility. As electronic and communication devices become lighter, smaller, and more advanced, technologies utilizing FCCL films have been evolving. As an example, FCCL films are applied in wearable devices, medical sensors, and flexible electronic devices, and there is a growing need for flexible substrates with high stretchability and durability utilizing such FCCL films.

### SUMMARY

An embodiment of the inventive concept may provide a flexible substrate with improved stretchability and durability.

According to an embodiment of the inventive concept, a flexible substrate may comprise a base layer and a pattern portion on the base layer, wherein the pattern portion includes a plurality of line portions extending in a first direction and spaced apart from each other in a second direction perpendicular to the first direction and a plurality of arc portions connecting the line portions to each other, and wherein the widths of the line portions in the second direction increase as they get closer to an edge region of the base layer.

According to an embodiment of the inventive concept, the aspect ratio of the pattern portion is 0.8 or greater.

According to an embodiment of the inventive concept, the pattern portion includes a polyimide pattern and a copper pattern on the polyimide pattern.

According to an embodiment of the inventive concept, a thickness of the polyimide pattern is 50 μm to 60 μm, a thickness of the copper pattern is 2 μm to 4μm, and wherein a minimum width of the line portions in the second direction is 50 μm to 60 μm.

According to an embodiment of the inventive concept, the line portions include a first line portion, a second line portion, and a third line portion, and the first line portion is positioned farthest from the edge region of the base layer, and the third line portion is positioned closest to the edge region of the base layer, and the second line portion is positioned between the first line portion and the third line portion.

According to an embodiment of the inventive concept, the first line portion has a first width in the second direction, the second line portion has a second width in the second direction, the third line portion has a third width in the second direction,

the second width is 1.5 times to 2.5 times the first width, and wherein the third width is 3 to 4 times the first width.

According to an embodiment of the inventive concept, the first line portion has a first length in the first direction, the second line portion has a second length in the first direction, the third line portion has a third length in the first direction, the second length is greater than the first length, and the third length is greater than the second length.

According to an embodiment of the inventive concept, the second length is 1.2 times to 1.7 times the first length, wherein the third length is 1.2 times to 1.7 times the second length.

According to an embodiment of the inventive concept, wherein the first line portions are provided in plurality along the second direction, and wherein the arc portion includes a first arc portion connecting the first line portions, a second arc portion connecting the first line portion and the second line portion and a third arc portion connecting the second line portion and the third line portion.

According to an embodiment of the inventive concept, the first arc portion has a first radius, the second arc portion has a second radius, the third arc portion has a third radius, the second radius is greater than the first radius, and the third radius is greater than the second radius.

According to an embodiment of the inventive concept, second radius is greater than the first radius by a width of the first line portion, and wherein the third radius is greater than the second radius by the width of the first line portion.

According to an embodiment of the inventive concept, the flexible substrate further comprises a pad portion on an edge region of the base layer and a connecting portion connecting the pattern portion and the pad portion.

According to an embodiment of the inventive concept, a flexible substrate may comprise a base layer having a center region and an edge region, a pattern portion on the center region of the base layer and a pad portion on the edge region of the base layer and connecting to the pattern portion, wherein the pattern portion includes a plurality of line portions extending in a first direction and spaced apart from each other in a second direction perpendicular to the first direction and a plurality of arc portions connecting the line portions, wherein an area of the line portions increases as the line portions get closer to the edge region in a plan view, and wherein each of the line portions and the arc portions includes a polyimide pattern and a copper pattern on the polyimide pattern.

According to an embodiment of the inventive concept, the copper pattern covers an upper surface of the polyimide pattern.

According to an embodiment of the inventive concept, wherein an area of the arc portions increases as the arc portions get closer to the edge region in a plan view.

According to an embodiment of the inventive concept, the polyimide pattern is exposed from the copper pattern, and the copper pattern is disposed at a center of the arc portion rather than the polyimide pattern in the arc portion.

According to an embodiment of the inventive concept, a width of the copper pattern is 50% to 80% of a width of the arc portion.

According to an embodiment of the inventive concept, wherein the pattern portion has an ‘S’ shape in a plan view, and wherein the base layer includes an elastomer.

### BRIEF DESCRIPTION OF THE DRAWINGS

FIG. 1 is a plan view of illustrating a flexible substrate according to some embodiments

of the inventive concept.

FIG. 2 is a cross-sectional view taken along line A-A′ of FIG. 1 according to some embodiments of the inventive concept.

FIG. 3 is an enlarged view of an arc portion according to some embodiments of the inventive concept.

FIG. 4 is a plan view of illustrating a flexible substrate according to some embodiments of the inventive concept.

FIG. 5 is a plan view of illustrating a flexible substrate according to some embodiments of the inventive concept.

FIGS. 6, 7, 8, 9, and 10 are cross-sectional views illustrating a process of fabricating a flexible substrate according to some embodiments of inventive concept.

### DETAILED DESCRIPTION

In order to fully understand the structure and effects of the inventive concept, preferred embodiments of the invention will be described with reference to the accompanying drawings. However, the present invention is not limited to the embodiments disclosed below and may be implemented in various forms with various modifications. The description of the embodiments is provided merely to ensure a complete disclosure of the invention and to fully convey the scope of the invention to those skilled in the art. In the accompanying drawings, the sizes of components may be illustrated larger than actual for clarity, and the proportions of the components may be exaggerated or reduced.

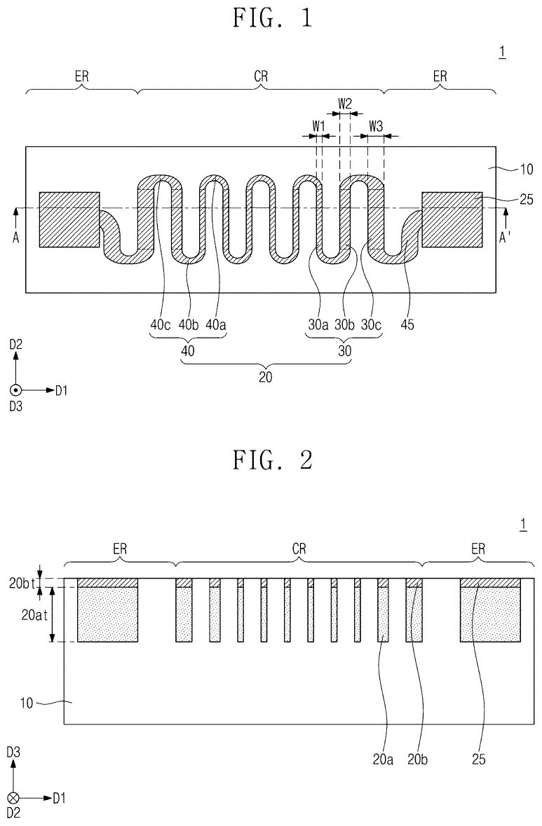

FIG. 1 is a plan view of illustrating a flexible substrate according to some embodiments of the inventive concept. FIG. 2 is a cross-sectional view taken along line A-A′ of FIG. 1 according to some embodiments of the inventive concept.

Referring to FIGS. 1 and 2, a flexible substrate 1 according to some embodiments of the inventive concept may include a base layer 10, a pattern portion 20, and a pad portion 25.

The base layer 10 may include a center region CR and an edge region ER. The edge region ER may be spaced apart from the center region CR in the first direction D1. In this specification, the first direction D1 is defined as a direction parallel to an upper surface of the flexible substrate 1. The second direction D2 is defined as a direction parallel to the upper surface of the flexible substrate 1 and perpendicular to the first direction D1. The third direction D3 is defined as a direction perpendicular to the upper surface of the flexible substrate 1. The base layer 10 may include an insulating material. For example, the base layer 10 may include an elastomer.

The pattern portion 20 may be provided on the center region CR of the base layer 10. The pad portion 25 may be provided on the edge region ER of the base layer 10. The pattern portion 20 can serve as a wiring in the flexible substrate 1. A plurality of pad portions 25 may be provided to be spaced apart from each other in the first direction D1 with the pattern portion 20 interposed therebetween. The pattern portion 20 and the pad portion 25 may be connected to each other through a connection portion 45 provided therebetween. The pattern portion 20 may have an ‘S’ shape from a plan view. That is, the pattern portion 20 may have a serpentine structure on the base layer 10.

Specifically, the pattern portion 20 may include a plurality of line portions 30 and arc portions 40. The line portions 30 may be spaced apart from each other in the first direction D1. The line portions 30 may be in a linear form extending in the second direction D2. The arc portions 40 may connect the line portions 30 to each other and may have a ‘U’ shape in a plan view.

The line portion 30 may include a first line portion 30a, a second line portion 30b, and a third line portion 30c. The first line portion 30a, the second line portion 30b, and the third line portion 30c may be provided in plurality. The first line portions 30a may be the lines positioned farthest from the edge region ER in the first direction D1. The third line portion 30c may be positioned closest to the edge region ER in the first direction D1. The second line portion 30b may be positioned between the first line portion 30a and the third line portion 30c.

The first to third line portions 30a, 30b, 30c may have, for example, a left-right symmetrical structure. The third line portion 30c and the pad portion 25 may be connected through the connection portion 45. For convenience of the description, six first line portions 30a and two second line portions 30b and two third line portions 30c are illustrated, but the inventive concept is not limited thereto. The number of the first to third line portions 30a, 30b, 30c can be variously combined and changed.

From a planar view, the width of the line portion 30 in the first direction D1 may increase as the line portion 30 gets closer to the edge region ER. Specifically, the first line portion 30a may have a first width W1 in the first direction D1. The first width W1 may be a minimum line width among widths of the line portion 30 in the first direction D1. The second line portion 30b may have a second width W2 in the first direction D1. The third line portion 30c may have a third width W3 in the first direction D1. The second width W2 may be, for example, 1.5 times to 2.5 times the first width W1. The third width W3 may be, for example, 3 times to 4 times the first width W1. For this reason, the area of the line portions 30 may increase as the line portions 30 get closer to the edge region ER.

The arc portion 40 may include a first arc portion 40a, a second arc portion 40b, and a third arc portion 40c. The first arc portion 40a, the second arc portion 40b, and the third arc portion 40c may be provided in plurality. The first arc portion 40a may connect the first line portions 30a to each other. The second arc portion 40b may connect the first line portion 30a that is closest to the edge region ER among the first line portions 30a and the second line portion 30b. The third arc portion 40c may connect the second line portion 30b and the third line portion 30c.

From a material point of view, the pattern portion 20 may include a polyimide pattern 20a and a copper pattern 20b on the polyimide pattern 20a as shown in FIG. 2. That is, each of the line portions 30 and the arc portions 40 may be formed of the polyimide pattern 20a and the copper pattern 20b. The copper pattern 20b may cover an upper surface of the polyimide pattern 20a. Therefore, the upper surface of the polyimide pattern 20a may not be exposed from the upper surface of the flexible substrate 1.

The aspect ratio of the pattern portion 20 may be 0.8 or greater. Specifically, the thickness 20at of the polyimide pattern 20a may be, for example, 50 μm to 60 μm. The thickness 20bt of the copper pattern 20b may be, for example, 2 μm to 4 μm. The line width of the pattern portion 20 may be, for example, 50 μm to 60 μm. In this case, the line width of the pattern portion 20 may correspond to the first width W1 of the first line portion 30a. As the aspect ratio of the pattern portion 20 is 0.8 or greater, deformation of the flexible substrate 1 in the vertical direction can be prevented, and the stretchability and durability of the pattern portion 20 can be improved.

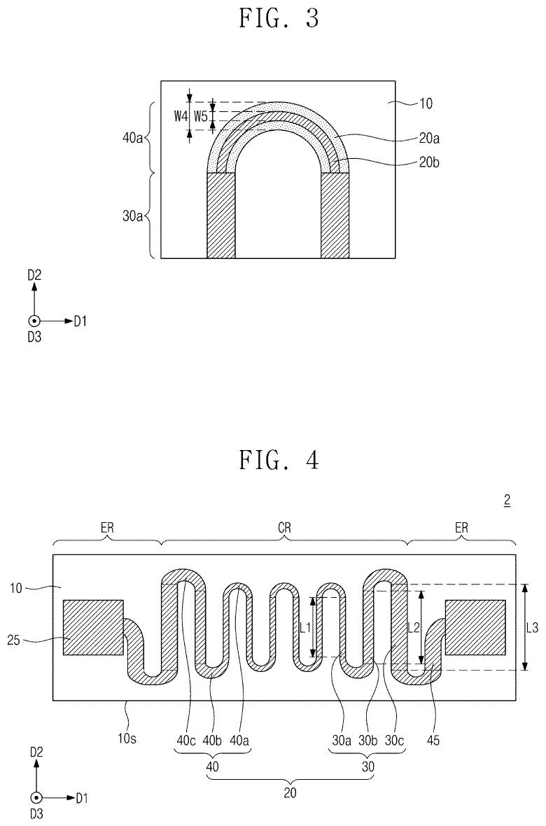

FIG. 3 is an enlarged view of an arc portion according to some embodiments of the inventive concept. Although FIG. 3 illustrates, as an example, the first line portions 30a and the first arc portion 40a connecting them, the shape of the first arc portions 40a according to the embodiment of FIG. 3 can be applied substantially equally to the second arc portion 40b and the third arc portion 40c.

Referring to FIG. 3, the upper surface of the polyimide pattern 20a may be exposed from the copper pattern 20b in the first arc portion 40a according to some embodiments of the inventive concept. The copper pattern 20b may be disposed at the center of the first arc portion 40a rather than the polyimide pattern 20a. That is, in the first arc portion 40a, the copper pattern 20b may be spaced apart from the base layer 10 with the polyimide pattern 20a therebetween. The copper pattern 20b may be connected to the first line portion 30a.

In this case, the first arc portion 40a may have a fourth width W4. The fourth width W4 may correspond to the sum of the width of the copper pattern 20b and the widths of the polyimide patterns 20a on both sides of the copper pattern 20b in the first arc portion 40a. The copper pattern 20b in the first arc portion 40a may have a fifth width W5. The fifth width W5 may be 50% and 80% of the fourth width W4. In this manner, as the copper pattern 20b is disposed at the center of the first arc portion 40a, cracks generated by the stress in the arc portions 40 can be prevented.

FIG. 4 is a plan view of illustrating a flexible substrate according to some embodiments of the inventive concept.

Referring to FIG. 4, from a plan view, the length of the line portion 30 of the flexible substrate 2 in the second direction D2 according to some embodiments of the inventive concept may increase as it gets closer to the pad portion 25, that is, the edge region ER.

Specifically, the first line portion 30a may have a first length L1 in the second direction D2. The second line portion 30b may have a second length L2 in the second direction D2. The third line portion 30c may have a third length L3 in the second direction D2.

The second length L2 may be greater than the first length L1. The third length L3 may be greater than the second length L2. The second length L2 may be, for example, 1.2 times to 1.7 times the first length L1. The third length L3 may be, for example, 1.2 to 1.7 times the second length L2. As the lengths of the line portions 30 increase closer to the edge region ER, the stress concentration near the edge region ER may be alleviated.

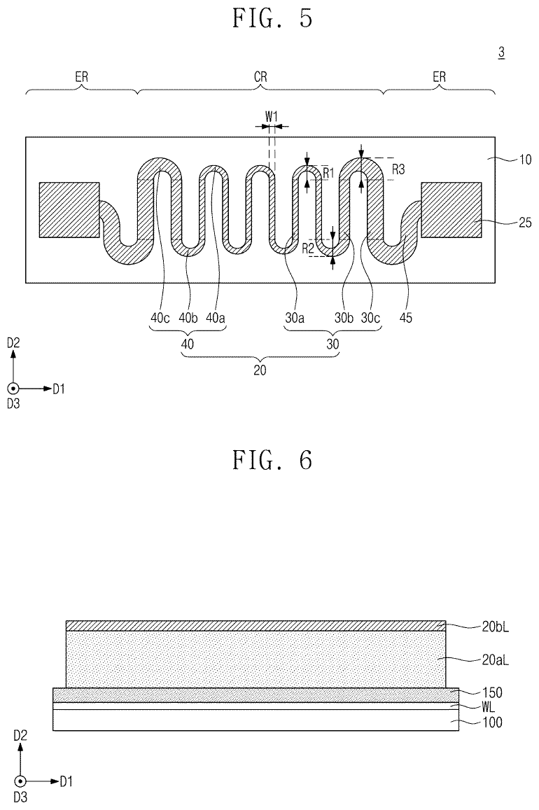

FIG. 5 is a plan view of illustrating a flexible substrate according to some embodiments of the inventive concept.

Referring to FIG. 5, from a plan view, in the flexible substrate 3 according to some embodiments of the inventive concept, a radius of the arc portion 40 may increase as it gets closer to the edge region ER. In this specification, the radius of the arc portion 40 may correspond to the radius of an imaginary circle defined based on the arc of the arc portion 40.

Specifically, the first arc portion 40a may have a first radius R1. The second arc portion 40b may have a second radius R2. The third arc portion 40c may have a third radius R3. The second radius R2 may be greater than the first radius R1. The third radius R3 may be greater than the second radius R2. The second radius R2 may be, for example, greater than the first radius R1 by the first width W1. The third radius R3 may be, for example, greater than the second radius R2 by the first width W1. Therefore, the area of the arc portions 40 may increase as the arc portions 40 get closer to the edge region ER. As the radius of the arc portions 40 increases as it gets closer to the edge region ER, cracking may be prevented from occurring near the edge region ER.

FIGS. 6, 7, 8, 9, and 10 are cross-sectional views illustrating a process of fabricating a flexible substrate according to some embodiments of inventive concept.

Referring to FIG. 6, a carrier substrate 100 may be provided. The carrier substrate 100 may include, for example, a glass substrate. A first film 150 may be provided on the carrier substrate 100. In this case, a liquid layer WL may be provided between the carrier substrate 100 and the first film 150. The liquid layer WL may include, for example, a liquid such as water, and the carrier substrate 100 and the first film 150 may be pressed together by the surface tension of water. The first film 150 may be, for example, an adhesive film.

Then, a polyimide layer 20aL and a copper layer 20bL may be formed on the first film 150. The polyimide layer 20aL and the copper layer 20bL may be extended in the first direction D1.

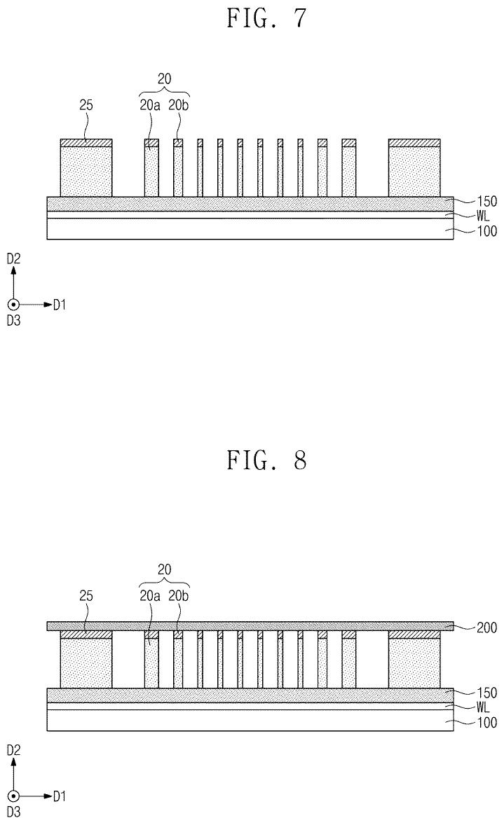

Referring to FIG. 7, a patterning process may be performed on the polyimide layer 20aL and the copper layer 20bL. The patterning process may be performed using, for example, UV laser with a wavelength of 355 nm. As a result of performing the patterning process, a plurality of polyimide patterns 20a and copper patterns 20b may be formed from the polyimide layer 20aL and the copper layer 20bL. The polyimide pattern 20a and the copper pattern 20b may form the pattern portion 20. At this time, the copper pattern 20b formed on the edge of the carrier substrate 100 can form the pad portion 25 described in FIG. 1.

Referring to FIG. 8, a second film 200 may be provided on the polyimide pattern 20a and the copper pattern 20b. The second film 200 may be in contact with an upper surface of the copper patterns 20b. The second film 200 may be, for example, a heat-release tape or a water-soluble tape.

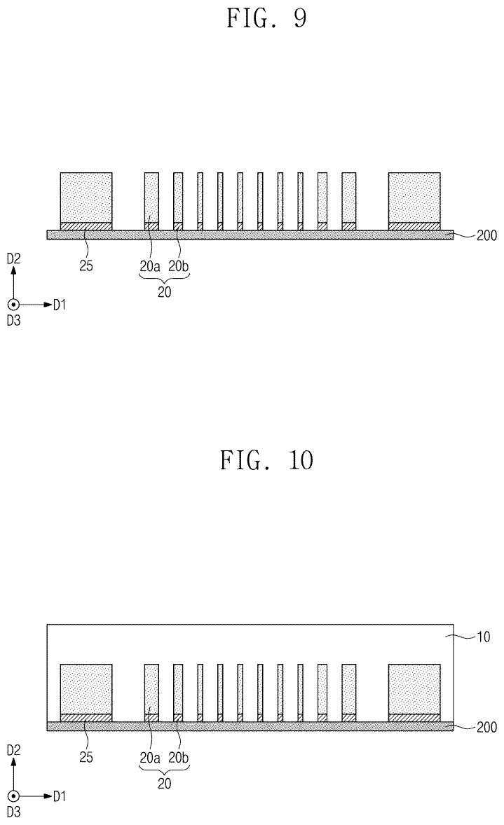

Referring to FIG. 9, the carrier substrate 100, the liquid layer WL, the first film 150, the pattern portion 20, and the second film 200 may be flipped. Thereafter, the carrier substrate 100, the liquid layer WL, and the first film 150 may be removed. As a result, the bottom surface of the polyimide pattern 20a may be exposed upward.

Referring to FIG. 10, a base layer 10 may be formed on the second film 200. The base layer 10 may fill the space between the plurality of polyimide patterns 20a and copper patterns 20b on the second film 200. The base layer 10 may include, for example, an insulating material such as an elastomer.

Thereafter, referring again to FIGS. 1 and 2, the base layer 10 may be flipped, and as the second film 200 on the pattern portion 20 is removed, a flexible substrate according to some embodiments of the inventive concept may be completed.

A wiring of a flexible substrate according to an embodiment of the inventive concept may include line portions extending in one direction and arc portions connecting the line portions. In this case, the width of the line portions may be increased as the line portions get closer to an edge region of the flexible substrate. Therefore, the stress concentration in the edge region of the flexible substrate can be alleviated and the stiffness of the wiring can be increased. As a result, a flexible substrate with improved structural stability can be provided.

While the embodiments of the inventive concept have been described above with reference to the accompanying drawings, it will be understood by those of ordinary skill in the art that the present invention may be embodied in other specific forms without changing the technical spirit or essential features of the invention. Therefore, it should be understood that the above-described embodiments are merely illustrative in all aspects and not restrictive.

What is claimed is:

1. A flexible substrate, comprising:
a base layer; and
a pattern portion on the base layer,
wherein the pattern portion includes a plurality of line portions extending in a first direction and spaced apart from each other in a second direction perpendicular to the first direction; and
a plurality of arc portions connecting the line portions to each other, and
wherein the widths of the line portions in the second direction increase as they get closer to an edge region of the base layer.

2. The flexible substrate of claim 1, wherein the aspect ratio of the pattern portion is 0.8 or greater.

3. The flexible substrate of claim 1, wherein the pattern portion includes a polyimide pattern and a copper pattern on the polyimide pattern.

4. The flexible substrate of claim 3, wherein:
a thickness of the polyimide pattern is 50 μm to 60 μm,
a thickness of the copper pattern is 2 μm to 4 μm, and
wherein a minimum width of the line portions in the second direction is 50 μm to 60 μm.

5. The flexible substrate of claim 1, wherein:
the line portions include a first line portion, a second line portion, and a third line portion,
the first line portion is positioned farthest from the edge region of the base layer,
the third line portion is positioned closest to the edge region of the base layer, and
the second line portion is positioned between the first line portion and the third line portion.

6. The flexible substrate of claim 5, wherein:
the first line portion has a first width in the second direction,
the second line portion has a second width in the second direction,
the third line portion has a third width in the second direction,
the second width is 1.5 times to 2.5 times the first width, and
the third width is 3 to 4 times the first width.

7. The flexible substrate of claim 5, wherein:
the first line portion has a first length in the first direction,
the second line portion has a second length in the first direction,
the third line portion has a third length in the first direction,
the second length is greater than the first length, and
the third length is greater than the second length.

8. The flexible substrate of claim 7, wherein:
the second length is 1.2 times to 1.7 times the first length, and
the third length is 1.2 times to 1.7 times the second length.

9. The flexible substrate of claim 5,
wherein the first line portions are provided in plurality along the second direction, and
wherein the arc portion includes a first arc portion connecting the first line portions;
a second arc portion connecting the first line portion and the second line portion; and
a third arc portion connecting the second line portion and the third line portion.

10. The flexible substrate of claim 9, wherein:
the first arc portion has a first radius,
the second arc portion has a second radius,
the third arc portion has a third radius,
the second radius is greater than the first radius, and
the third radius is greater than the second radius.

11. The flexible substrate of claim 10, wherein the second radius is greater than the first radius by a width of the first line portion, and
wherein the third radius is greater than the second radius by the width of the first line portion.

12. The flexible substrate of claim 1, further comprising:
a pad portion on the edge region of the base layer; and
a connecting portion connecting the pattern portion and the pad portion.

13. A flexible substrate, comprising:
a base layer having a center region and an edge region;
a pattern portion on the center region of the base layer; and
a pad portion on the edge region of the base layer and connecting to the pattern portion,
wherein the pattern portion includes:
a plurality of line portions extending in a first direction and spaced apart from each other in a second direction perpendicular to the first direction; and
a plurality of arc portions connecting the line portions,
wherein an area of the line portions increases as the line portions get closer to the edge region in a plan view, and
wherein each of the line portions and the arc portions includes a polyimide pattern and a copper pattern on the polyimide pattern.

14. The flexible substrate of claim 13, wherein the copper pattern covers an upper surface of the polyimide pattern.

15. The flexible substrate of claim 13, wherein an area of the arc portions increases as the arc portions get closer to the edge region in a plan view.

16. The flexible substrate of claim 13, wherein:
the polyimide pattern is exposed from the copper pattern, and
the copper pattern is disposed at a center of the arc portion rather than the polyimide pattern in the arc portion.

17. The flexible substrate of claim 16, wherein a width of the copper pattern is 50% to 80% of a width of the arc portion.

18. The flexible substrate of claim 13, wherein the pattern portion has an ‘S’ shape in a plan view, and
wherein the base layer includes an elastomer.
